(19) United States
(12) Patent Application Publication
(10) Pub. No.: US 2006/0017350 A1
(43) Pub. Date: Jan. 26, 2006

(54) Piezoelectric element driving circuit and remote controller using the same

(75) Inventors: Tetsuro Hanahara, Tsuruga-shi (JP); Syosaku Matsumiya, Mikatakaminaka-gun (JP); Noriaki Matsui, Tsuruga-shi (JP)

Correspondence Address: RATNERPRESTIA, P O BOX 980, VALLEY FORGE, PA, 19482-0980, US

(73) Assignee: Matsushita Electric Industrial Co., Ltd.

(21) Appl. No.: 11/154,251

(22) Filed: Jun. 16, 2005

(30) Foreign Application Priority Data
Jul. 21, 2004 (JP) 2004-212720

(51) Int. Cl. H01L 41/09

(52) U.S. Cl. 310/317

(57) ABSTRACT

A piezoelectric element driving circuit includes a piezoelectric element, a switching element, and a coil. The piezoelectric element generates at least one of sound and vibration. The switching element turns on/off the application of a voltage to the piezoelectric element at regular intervals. The coil is connected in parallel with the piezoelectric element. A remote controller includes the piezoelectric element driving circuit, a receiving circuit, and a controlling circuit. The receiving circuit receives a signal for searching the remote controller. The controlling circuit is connected to the piezoelectric element driving circuit and the receiving circuit, and operates the piezoelectric element driving circuit when the receiving circuit receives the search signal.

### BACKGROUND OF THE INVENTION

1. Field of the Invention

The present invention relates to a piezoelectric element driving circuit and a remote controller incorporating the circuit and used mainly for various kinds of electronic equipment.

2. Background Art

In recent years, various kinds of electronic equipment, such as a television set and audio and air-conditioning equipment, are remote-controlled in the living room or the cabin of an automobile using a remote controller. Additionally, there is a remote controller incorporating a piezoelectric element driving circuit that is operated by a predetermined operation so that the remote controller can easily be found even when hidden under baggage or a gap between the seats. Such a remote controller is disclosed in Japanese Patent Unexamined Publication No. 2000-22562, for example. Such a conventional piezoelectric element driving circuit of a remote controller is described with reference to FIGS. 4 and 5.

FIG. 4 is a circuit diagram of the conventional piezoelectric element driving circuit. Resistor 22 is connected in parallel with piezoelectric buzzer (hereinafter referred to as “buzzer”) 21. One end of buzzer 21 is connected to a power supply of 5V DC, such as a battery. The collector of transistor 23 is connected to buzzer 21. The base thereof is coupled to clock circuit 25 via resistor 24. Thus, the piezoelectric element driving circuit is structured.

The remote controller includes a circuit board (not shown) and a housing made of an insulating resin and covering the circuit board. On the top and bottom faces of the circuit board, the piezoelectric element driving circuit, a controlling circuit, and a receiving circuit (neither shown) are formed. When the remote controller is directed to electronic equipment and a predetermined key protruding from the housing vertically movable is pressed, an infrared remote-control signal corresponding to the key is transmitted from the controlling circuit to the equipment. This operation can turn on/off a television set, or audio or air-conditioning equipment, or adjust sound volume by remote control.

When a remote controller is hidden under baggage or a gap between the seats and cannot be found, a user operates a switch provided on the electronic equipment or the vehicle. Then, a radio wave search signal is transmitted from the equipment or the vehicle. The receiving circuit of the remote controller receives the search signal. Thus, the controlling circuit operates the piezoelectric element driving circuit.

At this time, as shown by the waveform of FIG. 5, a supply voltage of 5V is applied to connection point 26 between buzzer 21 and transistor 23 when transistor 23 is turned off. On the other hand, when the receiving circuit receives a search signal, the controlling circuit operates the piezoelectric element driving circuit and turns on transistor 23, the voltage decreases to 0V. In this manner, according to the clock signals from clock circuit 25, transistor 23 repeats this on/off operation at regular intervals.

In other words, while the receiving circuit receives a search signal and the piezoelectric element driving circuit operates, voltages of 0V and 5V are applied to buzzer 21 at regular intervals. As a result, buzzer 21 intermittently sounds. This beep sound allows the user to locate and easily find the remote controller.

However, for the conventional remote controller, because buzzer 21 is driven by a supply voltage of 5V, beep sound thereof is small. For this reason, when the remote controller is hidden under large baggage or inner gap of the seats, it is difficult to hear the beep sound and find the remote controller. To make the beep sound larger, an additional circuit, such as a booster circuit, is required.

### SUMMARY OF THE INVENTION

A piezoelectric element driving circuit of the present invention includes a piezoelectric element, a switching element, and a coil. The piezoelectric element generates at least one of sound and vibration. The switching element turns on/off the application of a voltage to the piezoelectric element at regular intervals. The coil is connected in parallel with the piezoelectric element. In this structure, the counter electromotive force of the coil increases the driving voltage of the piezoelectric element. This can provide a piezoelectric element driving circuit that has a simplified structure and can generate a large beep sound. A remote controller incorporating this piezoelectric element driving circuit includes a receiving circuit and a controlling circuit. The receiving circuit receives a search signal such that a user can search the remote controller. The controlling circuit is connected to the piezoelectric element driving circuit and the receiving circuit, and operates the piezoelectric element driving circuit when the receiving circuit receives the search signal. The remote controller thus structured can easily be found.

### BRIEF DESCRIPTION OF THE DRAWINGS

FIG. 1 is a circuit diagram of a piezoelectric element driving circuit in accordance with an exemplary embodiment of the present invention.

FIG. 2 is a sectional view of a remote controller incorporating the piezoelectric element driving circuit of FIG. 1.

FIG. 3A shows a voltage waveform assumed in the piezoelectric element driving circuit of FIG. 1.

FIG. 3B shows a voltage waveform generated in the piezoelectric element driving circuit of FIG. 1.

FIG. 4 is a circuit diagram of a conventional piezoelectric driving circuit.

FIG. 5 shows a voltage waveform generated in the piezoelectric element driving circuit of FIG. 4.

### DETAILED DESCRIPTION OF THE INVENTION

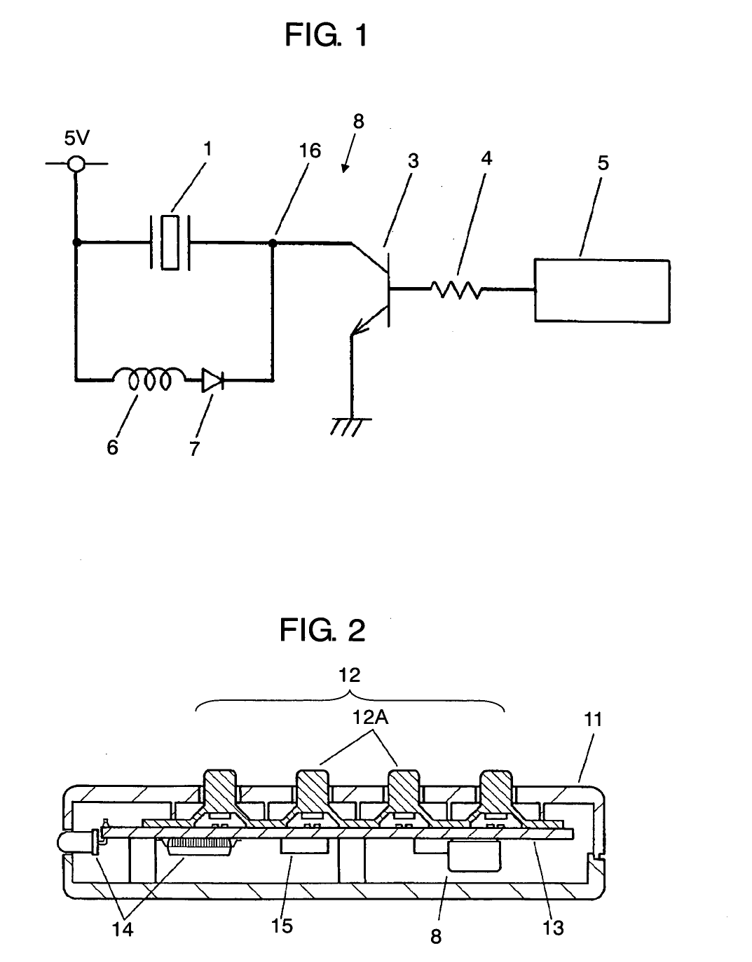

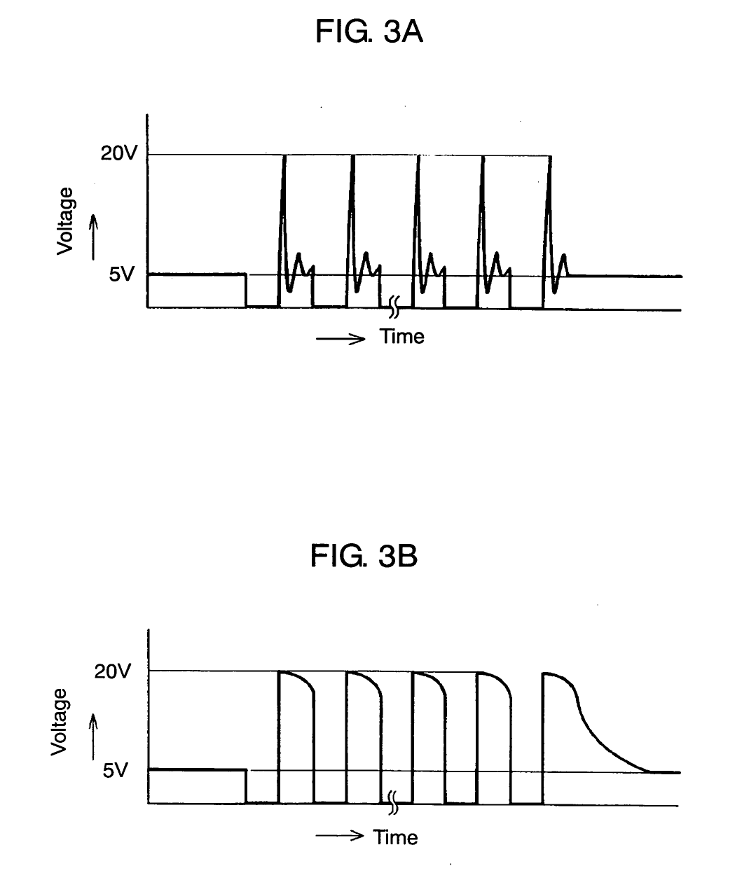

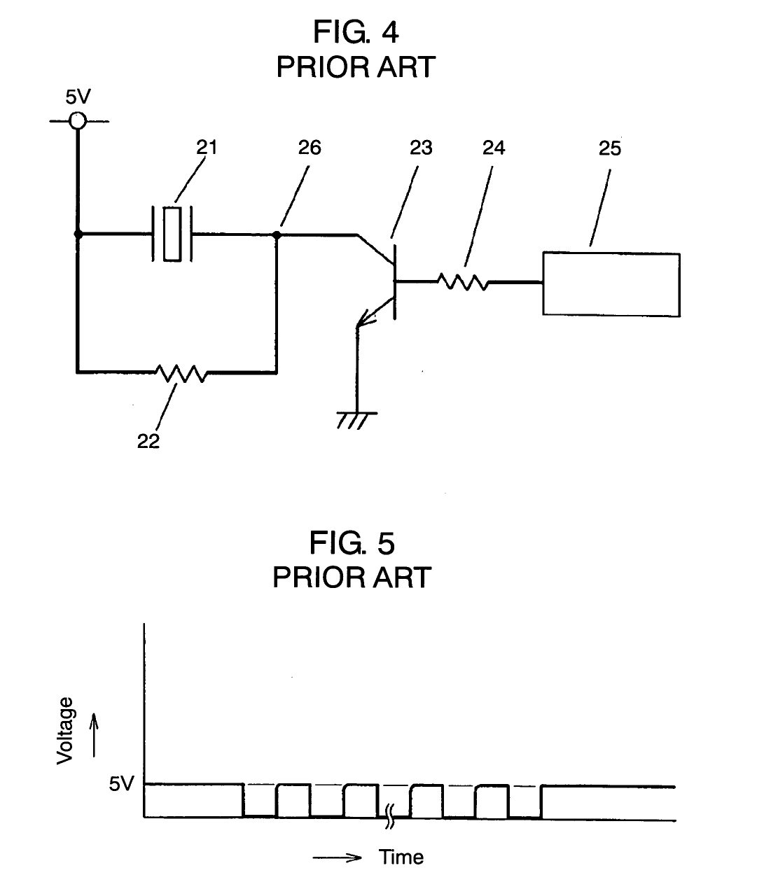

FIG. 1 is a circuit diagram of a piezoelectric element driving circuit in accordance with an exemplary embodiment of the present invention. FIG. 2 is a sectional view of a remote controller incorporating the piezoelectric element driving circuit of FIG. 1. FIG. 3A shows a voltage waveform assumed in the piezoelectric element driving circuit of FIG. 1. FIG. 3B shows an actual voltage waveform thereof.

In FIG. 1, one end of piezoelectric buzzer (hereinafter referred to as “buzzer”) 1 as a piezoelectric element, is connected to a power supply of 5V DC, such as a battery. The other end of buzzer 1 is connected to the collector of transistor 3 as a switching element. In Instead of buzzer 1 which generates sound, a piezoelectric element which generates vibration or both sound and vibration can be used.

The base of transistor 3 is coupled to clock circuit 5, such as a quarts oscillator, via resistor 4. Coil 6 is connected in parallel with buzzer 1. Between buzzer 1 and coil 6, diode 7 as a rectifier element, is connected. Diode 7 is provided for regulating electric current to flow from coil 6 to buzzer 1. Thus, piezoelectric element driving circuit (hereinafter referred to as “circuit”) 8 is structured.

FIG. 2 is a sectional view of a remote controller using circuit 8. On the top face of substantially box-shaped housing 11 made of insulating resin, such as polystyrene and acrylonitrile-butadiene-styrene (ABS), operating part 12 is formed. Operating part 12 has a plurality of keys 12A made of rubber or insulating resin, each protruding vertically movable. The bottom face of each key has switch contacts.

Housed in housing 11 is circuit board (hereinafter referred to as “board”) 13 that is made of paper phenol copper clad laminates or epoxy including glass and has a plurality of wiring patterns formed of cupper foil or the like on the top and bottom faces thereof. Circuit 8 is formed of buzzer 1, transistor 3, coil 6, diode 7, and other components mounted on board 13.

Further, on board 13, controlling circuit 14 is formed of electronic components, such as a microcomputer and a light emitting diode (LED). Receiving circuit 15 is formed of an antenna and other components. Thus, the remote controller is structured.

When predetermined key 12A of the remote controller is pressed in the above-described structure, the corresponding switch contacts formed on the bottom face of key 12A are brought into electric contact with each other. Controlling circuit 14 detects this operation state and transmits an infrared remote-control signal corresponding to the operation state to the equipment. Thus, a television set, or audio or air-conditioning equipment is powered on/off, or sound volume is adjusted by remote control, for example.

However, when a remote controller is hidden under baggage or a gap between the seats and is not found, a user operates a switch provided on the electronic equipment or vehicle. Then, a radio wave for searching the remote controller is transmitted from the equipment or vehicle and is received by receiving circuit 15 of the remote controller. Thus, controlling circuit 14 operates circuit 8.

Now, a supply voltage of approximately 5V is applied to connection point 16 between buzzer 1 and transistor 3 as shown in FIG. 3A, when transistor 3 is turned off. On the other hand, when a search signal is received and controlling circuit 14 operates circuit 8 and turns on transistor 3, the voltage decreases to 0V. In this manner, according to the clock signals from clock circuit 5, transistor 3 repeats this on/off operation to turn on/off the application of a voltage to buzzer 1 at regular intervals.

Next, when transistor 3 is turned off responsive to a clock signal from clock circuit 5, coil 6 connected in parallel with buzzer 1 generates a counter electromotive force of approximately 20 V, which is larger than a supply voltage of 5V. Thus, a voltage having an irregular waveform as shown in FIG. 3A attempts to be applied to connection point 16. In this manner, a voltage of approximately 20V, which is larger than a supply voltage of 5V, is applied to buzzer 1. Thus, a large beep sound can be generated.

Further, between buzzer 1 and coil 6, diode 7 is provided for regulating electric current to flow from coil 6 to buzzer 1 counter-clockwise. Thus, a voltage having an irregular waveform as shown in FIG. 3A is not applied to buzzer 1. However, a voltage of 20V having a regular waveform with a smaller loss as shown in FIG. 3B is applied thereto counter-clockwise.

While controlling circuit 14 operates circuit 8 responsive to a search signal, transistor 3 repeats this on/off operation at regular intervals. With this structure, a voltage of 0V is applied to buzzer 1 at the on state, and a voltage of approximately 20V, which is larger than a supply voltage of 5V with a smaller loss, is applied thereto at the off state repeatedly. Thus, buzzer 1 intermittently sounds.

In this manner, diode 7 applies driving voltage from coil 6 to buzzer 1 counter-clockwise without any power loss. Coil 6 generates a counter electromotive force and applies a voltage increased to approximately 20 V to buzzer 1. In other words, while circuit 8 operates, a voltage of approximately 20 V is repeatedly applied to buzzer 1. Thus, buzzer 1 intermittently makes a large beep sound. The large beep sound allows the user to locate and easily find the remote controller.

As described above, in this exemplary embodiment, coil 6 is connected in parallel with buzzer 1 as a piezoelectric element. Additionally, diode 7 as a rectifier element is provided between coil 6 and buzzer 1 for regulating electric current to flow from coil 6 to buzzer 1. This structure can increase the driving voltage and drive buzzer 1 in one current direction without any power loss. This can provide a piezoelectric element driving circuit that has a simplified structure and can generate a large beep sound and a remote controller that can easily be found.

As described above, the piezoelectric element driving circuit and the remote controller using the circuit of the present invention can generate a large beep sound with a simplified structure and be found easily. These are useful mainly for remote-controlling various kinds of electronic equipment.

What is claimed is:

1. A piezoelectric element driving circuit comprising:
a piezoelectric element for generating at least one of sound and vibration;
a switching element for turning on and off application of a voltage to the piezoelectric element at regular intervals; and
a coil coupled in parallel with the piezoelectric element.

2. The piezoelectric element driving circuit of claim 1, further comprising:
a rectifier element provided between the coil and the piezoelectric element for regulating electric current to flow from the coil to the piezoelectric element.

3. A remote controller comprising:
a piezoelectric element driving circuit including:
a piezoelectric element for generating at least one of sound and vibration;
a switching element for turning on and off application of a voltage to the piezoelectric element at regular intervals; and
a coil coupled in parallel with the piezoelectric element;
a receiving circuit for receiving a signal for searching the remote controller; and
a controlling circuit coupled to the piezoelectric element driving circuit and the receiving circuit for operating the piezoelectric element driving circuit when the receiving circuit receives the signal.

4. The remote controller of claim 3, wherein the piezoelectric element driving circuit further includes a rectifier element provided between the coil and the piezoelectric element for regulating electric current to flow from the coil to the piezoelectric element.
